(19) United States
(12) Patent Application Publication
(10) Pub. No.: US 2007/0194297 A1
(43) Pub. Date: Aug. 23, 2007

(54) Quantum Dot Switching Device

(75) Inventors: Wil McCarthy, Lakewood, CO (US); Richard M. Powers, Lakewood, CO (US); Gary E. Snyder, Lakewood, CO (US)

Correspondence Address: HENSLEY KIM & EDGINGTON, LLC, 1660 LINCOLN STREET, SUITE 3050, DENVER, CO, 80264, US

(73) Assignee: THE PROGRAMMABLE MATTER CORPORATION, Lakewood, CO (US)

(21) Appl. No.: 11/676,785

(22) Filed: Feb. 20, 2007

Related U.S. Application Data
(60) Provisional application No. 60/774,714, filed on Feb. 17, 2006.

(51) Int. Cl. H01L 31/00

(52) U.S. Cl. 257/14

(57) ABSTRACT

A multifunctional, programmable quantum confinement switching device uses the quantum confinement of charge carriers to operate on an input signal or energy and to release an output signal or energy. Energy enters the device through an input path and leaves through an output path, after being selectively blocked or modified by the switching action of the device under the influence of a control path. The quantum confinement of charge carriers as an artificial atom within a layer of the device in a quantum well or a quantum dot operates as the switch. The artificial atoms serve as dopants within a material supporting the device and are directly related to the voltage between the control path and a ground plane. The electrical, optical, thermal, or other energy passing through the device is selectively blocked, regulated, filtered, or modified by the doping properties of the artificial atoms. The remaining, unblocked energy is then free to exit the device through the output path.

### CROSS REFERENCE TO RELATED APPLICATIONS

This application claims priority pursuant to 35 U.S.C. §119(e) to U.S. Provisional application No. 60/774,714 filed 17 Feb. 2006 entitled “Quantum dot switching device.” This application is also related to U.S. Pat. No. 6,978,070 B1 and U.S. patent application Ser. Nos. 11/081,777, 11/081,778, 11/145,417 and 11/144,326.

### BACKGROUND

This disclosure relates to semiconductor switches, doping of semiconductor materials and the formation of quantum dots in semiconductor materials. This disclosure has particular, but not exclusive, application to electronic, optical, electro-optical, and thermal control systems for regulating or modifying the flow of energy.

The fabrication of very small structures to exploit the quantum mechanical behavior of charge carriers e.g., electrons or electron “holes” is well established. Quantum confinement of a carrier can be accomplished by a structure whose dimension is less than the quantum mechanical wavelength of the charge carrier. Confinement in a single dimension produces a “quantum well,” and confinement in two dimensions produces a “quantum wire.”

A “quantum dot” is a structure capable of confining charge carriers in all three dimensions. Quantum dots can be formed as particles, with a dimension in all three directions of less than the de Broglie wavelength of a charge carrier. Quantum confinement effects may also be observed in particles of dimensions less than the electron-hole Bohr diameter, the carrier inelastic mean free path, and the ionization diameter, i.e., the diameter at which the charge carrier's quantum confinement energy is equal to its thermal-kinetic energy. It is postulated that the strongest confinement may be observed when all of these criteria are met simultaneously. Such particles may be composed of semiconductor materials (for example, Si, GaAs, AlGaAs, InGaAs, InAlAs, InAs, and other materials), or of metals, and may or may not possess an insulative coating. Such particles are referred to in this document as “quantum dot particles.”

A quantum dot can also be formed inside a semiconductor substrate through electrostatic confinement of the charge carriers. This is accomplished through the use of microelectronic devices of various design, e.g., an enclosed or nearly enclosed electrode formed on top of a quantum well. Here, the term “micro” (as in “microelectronic devices”) means “very small” and usually expresses a dimension of or less than the order of microns (thousandths of a millimeter). The term “quantum dot device” refers to any apparatus capable of generating a quantum dot in this manner. The generic term “quantum dot” refers to the confinement region of any quantum dot particle or quantum dot device.

A quantum dot device may be formed by creating a quantum well in a transport layer of a semiconductor (similar to the negative layer of a P-N-P junction) surrounded by barrier or supply layers of a semiconductor with higher conduction energy (similar to the positive layers of a P-N-P junction). Conductors may serve as the electrodes of the quantum dot device. These electrodes confine charge carriers in the quantum well into a small space or quantum dot when a reverse-bias voltage is applied, since the negative charge on the electrodes repels electrons, preventing their horizontal escape through the transport layer.

A quantum dot can be thought of as an “artificial atom,” since the charge carriers confined in it behave similarly in many ways to electrons confined by an atomic nucleus. A change in the energy level applied to a quantum dot can vary the number of confined electrons and thus the “atomic number” of the artificial atom. Note that as the artificial atom has no nucleus, and thus no protons, the term “atomic number” is used herein to refer to the number of electrons forming valence shells of the artificial atom. The term “artificial atom” is now in common use, and is often used interchangeably with “quantum dot.” However, for the purposes of this document, “artificial atom” refers specifically to the pattern of confined carriers, e.g., an electron gas or cloud, and not to the particle or device in which the carriers are confined.

The electrical, optical, thermal, magnetic, mechanical, and chemical properties of a material depend on the structure and excitation level of the electron clouds surrounding its atoms and molecules. Doping is the process of embedding precise quantities of carefully selected impurities in a material in order to alter the electronic structure of the surrounding atoms, for example, by donating or borrowing electrons from them. Doping may alter the material's electrical, optical, thermal, magnetic, mechanical, or chemical properties. Impurity levels as low as one dopant atom per billion atoms of substrate can produce measurable deviations from the expected behavior of a pure crystal, and deliberate doping to levels as low as one dopant atom per million atoms of substrate are commonplace in the semiconductor industry, for example, to alter the conductivity of a semiconductor.

The embedding of metal and semiconductor nanoparticles inside bulk materials (e.g., the lead particles in leaded crystal) has occurred for centuries. However, an understanding of the physics of these materials has only been achieved comparatively recently. These nanoparticles are quantum dots with characteristics determined by their size and composition. These nanoparticles serve as dopants for the material in which they are embedded to alter selected optical or electrical properties. The “artificial atoms” represented by these quantum dots have properties which differ in useful ways from those of natural atoms.

Similarly, once the charge carriers are trapped in a quantum dot they form an artificial atom that is capable of serving as a dopant. Increasing the voltage on the electrodes by a specific amount forces a specific number of additional carriers into the quantum dot, altering the atomic number of the artificial atom trapped inside. Conversely, decreasing the voltage by a specific amount allows a specific number of carriers to escape to regions of the transport layer outside the quantum dot. Thus, the doping properties of the artificial atom may be adjusted in real time through variations in the signal voltage of the control wires leading to the electrodes.

Quantum dots can have a greatly modified electronic structure from the corresponding bulk material, and therefore different properties. Quantum dots can also serve as dopants inside other materials. Because of their unique properties, quantum dots are used in a variety of electronic, optical, and electro-optical devices. Quantum dots are currently used as near-monochromatic fluorescent light sources, laser light sources, light detectors including infra-red detectors, and highly miniaturized transistors, including single-electron transistors. They can also serve as a useful laboratory for exploring the quantum mechanical behavior of confined carriers.

A single-electron transistor (SET) is a type of switch that operates pursuant to principles of quantum confinement. The SET consists of a source (input) path leading to a quantum dot particle or quantum dot device, and a drain (output) path exiting, with a gate electrode controlling the dot. With the passage of one electron through the gate path into the device, the switch converts from a conducting or closed state to a nonconducting or open state, or vice-versa.

Thermal switches allow the passage of heat energy in their ON or closed state, but prevent it in their OFF or open state. Thermal switches are generally mechanical relays, which rely on contact between two conducting surfaces (typically made of metal) to enable the passage of heat. When the two surfaces are withdrawn, heat energy is unable to conduct between them except through the air gap. If a thermal switch is placed in vacuum, heat conduction is prevented entirely. Another type of thermal switch involves pumping a gas or liquid in or out of a chamber. When the chamber is full, it conducts heat. When empty, it doesn't.

Optical switches also exist. Light can be blocked by optical filters which absorb or reflect certain frequencies while allowing others to pass through. Highpass and lowpass filters may be used, or a narrow range of frequencies can be blocked by a notch filter or bandblock filter. Some filters also incorporate quantum wells, quantum wires, or quantum dot particles as dopants (much as leaded crystal incorporates lead atoms or particles as dopants) to fix the optical properties at the time of manufacture.

The addition of a mechanical shutter can turn an otherwise transparent material—including a filter—into an optical switch. When the shutter is open, light passes through easily. When the shutter is closed, no light passes. If the mechanical shutter is replaced with an electrodarkening material such as a liquid crystal, then the switch is “nearly solid state”, with no moving parts except photons, electrons, and the liquid crystal molecules themselves. This principle is used, for example, in LCD displays, where the white light from a backdrop is passed through colored filters and then selectively passed through or blocked by liquid crystal materials controlled by a transistor. The result is a two-dimensional array of colored lights which form the pixels of a television or computer display. Such optical filter/switch combinations pass or block the exact same frequencies of light as determined at the time of manufacture.

The information included in this Background section of the specification, including any references cited herein and any description or discussion thereof, is included for technical reference purposes only and is not to be regarded as subject matter by which the scope of the invention is to be bound.

### SUMMARY

The present invention is directed to the use of electrically addressable quantum dots within a layered composite film to produce a solid-state, multifunctional, programmable, quantum confinement switch device within the film. The term “multifunctional, programmable, quantum confinement switch” (hereinafter a “quantistor”) refers to a solid-state device or component with an input path, an output path, and one or more control paths, which uses the quantum confinement of charge carriers to operate on the input signal or energy to produce the output signal or energy. Such operations include but are not limited to amplification, attenuation, transmission, diversion, rotation, acceleration, shifting, reflection, absorption, delay, echo or repetition, inversion, limiting or clipping, distortion, purification or filtering, regulation, reshaping, reallocation, oscillation, identification or characterization, and storage.

Quantum-confined carriers have the ability to serve as dopants within the surrounding material and the quantistor's operations arise as a consequence of the resulting changes in the optical, electrical, thermal, magnetic, chemical and mechanical properties of the material. The specific operations in this list should not be construed as limiting the scope of the invention, but rather as explanatory examples to convey the nature and capabilities of the present invention, which is both multifunctional and programmable and may therefore be used for a multiplicity of operations. This is analogous to a digital computer, whose nature can be fully understood without an exhaustive list of the calculations it can perform.

The quantistor includes a sandwich of heterogeneous materials composed of, or incorporating, quantum confinement devices which may alter the bulk electrical, thermal, optical, magnetic, mechanical, and chemical properties of the sandwich, thus affecting the flow of electricity, heat, light, and other energy through the composite film. An energy-transporting structure—hereinafter referred to as the surface electrode, which is controlled via the control path—is included in the composite film to control the properties of the quantum dot dopants using external energy sources, even when the quantum dot dopants are embedded in solid materials, including opaque or electrically insulating materials that would ordinarily isolate the quantum dots from external influences. This electrode is equivalent to the “gate” electrode in a solid-state switch or valve such as a transistor, while the control path is analogous to the transistor's gate path. The addition of input and output pathways (analogous to a transistor's source and drain paths), whether physically connected to the device or existing in free space, then causes the composite film to serve as a quantistor.

The charge carriers are driven into the quantum dots by the energy in control paths and are trapped in the quantum dots through quantum confinement, such that the charge carriers form artificial atoms, which serve as dopants for the surrounding materials. The “atomic number” of each artificial atom is adjusted through precise variations in the voltage across the quantum dot that confines it. The change in atomic number alters the doping characteristics of the artificial atoms.

In some embodiments, the excitation level of the artificial atom is also controlled, either through additional electrical voltages or through optical or electromagnetic stimulation. Additionally, in some embodiments, the energy in the control paths creates electric fields that affect the quantum confinement characteristics of the quantum dots. This produces controlled and repeatable distortions in the size and shape of the artificial atoms, further altering their doping characteristics with a corresponding effect on the surrounding materials.

Since the electromagnetic (i.e., electrical, optical, and magnetic), thermal, mechanical, and chemical properties of a material depend on its electronic structure, and since the embedding of dopants can affect this structure, the programmable dopant composite film of the present invention offers a means for controlling the interior properties of a bulk material in real time. These material effects are a consequence of manipulating the internal electron arrangements of the bulk material, i.e., its electronic structure.

The function of quantum dots as dopants has been recognized in certain instances, for example, in thin films and on the surfaces of microchips. Quantum dots can have a greatly modified electronic structure from the corresponding bulk material, and therefore exhibit different material properties, for example, different optical and electrical properties.

The present invention reorganizes these principles and devices to form a quantum dot switching device for operating on an input signal or energy to produce an output signal or energy, under the influence of one or more control signals or energies. As noted above, the quantistor is analogous in many ways to a solid-state switch or valve, and in fact it can be used as one. However, it can also serve as a programmable diode (including a light-emitting diode, or a light-absorbing diode such as a photodiode), a heterojunction, a superlattice, or other layered structure, and can perform a vast number of other operations as a function of its programmable internal composition.

The quantistor device can include multiple surface electrodes, so that the quantum confinement properties—and thus the electrical, thermal, and optical conductivity, as well as other properties—can vary from one region of the device to the next. It should also be noted that as a side effect of its design, the device is also capable of emitting light through fluorescence, photoluminescence and, electroluminescence, and of absorbing light and generating an electrical current via the photoelectric effect. When configured internally as a thermoelectric Peltier junction or Thompson path (i.e., with multiple surface electrodes forming n-type regions and/or p-type regions, connected by conductive material on one face and connected only to the input and output paths on the other face), the device can also use a temperature gradient to generate electricity, or use electricity to generate a temperature gradient. These functions are incidental to the actual operation of the quantistor as a switch, i.e., they are side effects which arise as a natural consequence of the programmable quantum confinement that the switch relies on. Other types of solid-state switches do not produce these effects.

A quantistor provides a multifunctional switch that can regulate the flow of light, heat, electricity, and other energy either singly or in simultaneous combination. The quantistor is also a solid-state switch. The quantistor contains no moving parts, other than photons and electrons. The quantistor is a programmable switch whose energy-regulating properties can be controlled externally, through the application of electrical energy to the surface electrode or electrodes. The quantistor is further a switch that is capable of generating light (for example, as an indicator of its internal quantum state), or generating electricity from incident light (e.g., via the photoelectric effect), or generating electricity from a temperature gradient, or producing a temperature gradient, as a side effect of its normal operation.

Multiple programmable dopant layers can be stacked into three-dimensional structures whose properties can be adjusted through external signals, forming a type of “smart material,” which is a bulk solid with variable electrical, optical, thermal, magnetic, mechanical, and chemical properties. These properties can be tuned in real time through the adjustment of the energies in the control paths that affect the properties of artificial atoms used as dopants. The resulting materials can contain artificial atoms of numerous and variable types, if desired. Thus, there is a large number of potential uses for materials based on these devices. The programmable dopants within the quantistor can be used to create new pathways within the device for carrying or operating on electrical, thermal, optical, and other energy. Thus, additional devices can be created inside the quantistor in the same way that straightforward electrical circuits can be created inside a field-programmable gate array (FPGA).

The quantistor, like any form of switch, can be used as a logic or memory element in a computing device, and a plurality of quantistors can be connected to create logic pathways of entirely novel types, e.g., computers which rely on heat instead of charge or magnetism to carry and store information. The quantistor can be used to create switches that use one type of energy (for example, light or heat) to selectively block or regulate the flow of another type of energy (for example, the flow of electrons or holes). These energies may or may not be modulated so as to carry information.

Other features, details, utilities, and advantages of the present invention will be apparent from the following more particular written description of various embodiments of the invention as further illustrated in the accompanying drawings and defined in the appended claims.

### BRIEF DESCRIPTION OF THE DRAWINGS

In the drawings, closely related figures have the same element numbers.

FIG. 1 is a schematic, cross-section view of one embodiment of a quantistor device depicting a quantum dot formed within a quantum well by surface electrodes addressed by control paths, and serving as a multifunctional, programmable, quantum confinement switch (quantistor) between an input path and output path.

FIG. 2 is a schematic representation of another embodiment of a quantistor device incorporating a quantum well to confine charge carriers in a two-dimensional layer, and an electrode to create an electric field across the quantum well to alter its quantum confinement properties via the Stark effect. This quantum confinement region then serves as a multifunctional, programmable, confinement switch between the input path and output path.

FIG. 3 is a schematic representation of portions of a quantistor device illustrating the quantum confinement of charge carriers in three dimensions—i.e., the formation of a quantum dot—by means of a quantum well or heterojunction, including one or more surface electrodes and control paths. This quantum dot serves as a quantistor between the input path and output path.

FIG. 4 is a schematic representation of another embodiment of a quantistor device illustrating an array of quantum dot devices formed by an electrode grid that confines charge carriers in a plurality of three-dimensional regions. This plurality of quantum dots then serves as a quantistor between the input path and output path.

FIG. 5 is a schematic representation of an additional embodiment of a quantistor device illustrating the quantum confinement of charge carriers in a three-dimensional region by a plurality of surface electrodes and control paths. This plurality of quantum dots then serves as an quantistor between the input path and output path, whose internal doping can be modified to include the junction of different materials, such as p-n junctions.

FIG. 6 is a schematic, cross-section representation of a further embodiment of a quantistor device, in which the quantum dots that form the quantistor are generated by conductive cleats that project into the quantum well layers.

FIG. 7 is a schematic, cross-section representation of a further embodiment of a quantistor device, in which the quantum dots that form the quantistor are generated by electrodes surrounding islands that have been etched out of the quantum well layers.

### DETAILED DESCRIPTION

This technology involves the use of quantum dots within a layered composite film to produce a plurality of real-time, programmable dopants within the film, to serve as a multifunctional, programmable device by altering the electrical, thermal, and optical conductivity of the film. Energy-transporting control paths—leading to surface electrodes—are placed in the composite film to control the properties of the quantum dot dopants using external energy sources. Charge carriers are driven into the quantum dots by the energy in control paths and are trapped in the quantum dots through quantum confinement, such that the charge carriers form artificial atoms which serve as dopants for the surrounding materials. The “atomic number” of each artificial atom is adjusted through precise variations in the voltage across the quantum dot that confines it. Note that as the artificial atom has no nucleus, and thus no protons, the term “atomic number” is used herein to refer to the number of electrons forming valence shells of the artificial atom. The change in atomic number alters the doping characteristics of the artificial atoms. When an input pathway and an output pathway are added to the device, it becomes a programmable, multifunctional, quantum confinement switch, defined herein as a “quantistor.”

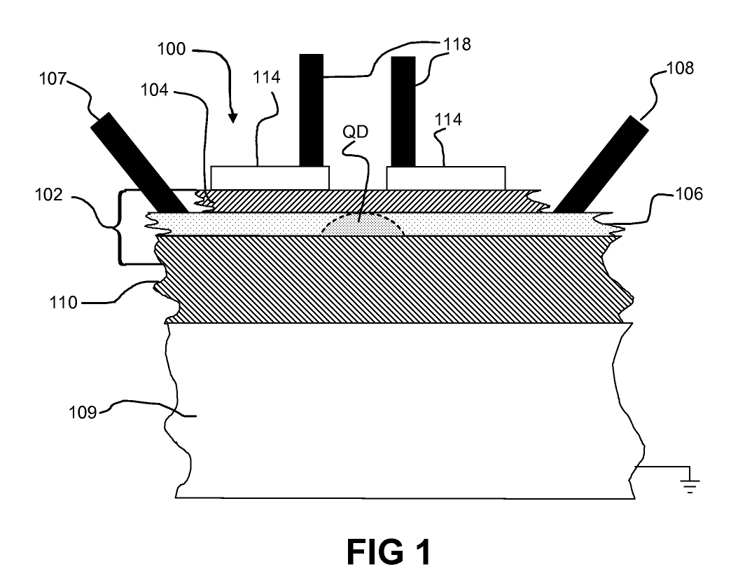

FIG. 1 depicts a cross-sectional view of a quantistor 100 according to one embodiment of the invention. The quantistor 100 is a sandwich of materials arranged so as to use an external energy source to produce quantum confinement effects which alter the electrical, optical, and thermal conductivity of the material. These quantum effects on the material further affect the energy flow, either permitting, restricting, or otherwise modifying the flow of energy from the input path 107 to the output path 108. The quantisitor 100 is formed as a layered composite including a conductive surface electrode 114, an upper barrier layer 104, a transport layer 106, and a lower barrier layer 110, which together form a quantum well 102, and a substrate or ground plane layer 109. The central or transport layer 106 of the quantum well 102 may consist of a semiconductor material, for example, GaAs, sandwiched between two barrier or supply layers 104 and 110 of a semiconductor material with higher conduction energy, for example, AlGaAs. An exemplary composition of the substrate or ground plane layer 109 is a semiconductor material, for example, GaAs, which has been doped so as to conduct electricity, and which serves as or is connected to the system's electrical ground. A reader of ordinary skill in the art will understand that a variety of other materials could be used, including but not limited to metals, conductive polymers, semiconductors, and superconductors.

Because of the difference in conduction energies, electrons settle preferentially into the lower energy of the GaAs transport layer 106, where they are free to travel horizontally, i.e., within the transport layer 106, but are confined “vertically” or perpendicular to the transport layer 106 by the higher conduction energy of the barrier layers 104 and 110. The semiconductor and oxide materials forming the transport layer 106 and the barrier layers 104 and 110 are held together by covalent bonds and, because of their three-dimensional crystal structure, they are strong, non-ductile materials. While brittle in bulk, these semiconductor and oxide materials can be formed into thin films or fibers which are flexible and can be used, for example, in fiberglass, flexible circuitry, or other applications where a combination of strength and flexibility is desirable. Other materials are not necessarily needed to strengthen or stabilize the quantistor 100.

The transport layer 106 of the quantum well 102 must be smaller in thickness than the de Broglie wavelength of the charge carriers for the charge carriers to be confined in the quantum well 102. For an electron at room temperature inside a solid material, this wavelength would be of order 15 nanometers. Thicker quantum wells are possible, although they will only exhibit quantum confinement of the charge carriers at temperatures colder than room temperature. Thinner quantum wells will operate at room temperature and at higher temperatures as long as the de Broglie wavelength of the charge carriers does not exceed the thickness of the transport layer 106.

There are numerous, established fabrication processes capable of producing material layers or films of appropriate thickness and purity to form a quantistor. These may include, but are not limited to, sputtering, chemical vapor deposition, molecular beam epitaxy, and chemically self-assembled layers, including monolayers. Less established, but plausible, alternative fabrication methods include wet chemical evaporation, electroplating, assembly by tailored microorganisms, molecular machines, direct-write nanolithography (e.g., dip pen nanolithography or nanoimprint lithography), atomic pick-and-place (e.g., with a scanning probe microscope), and atom holography (e.g., deposition of Bose-Einstein condensates). Other viable methods, although not listed here, may also be used and this listing should not be construed as limiting in scope.

The surface of the quantistor 100 includes conductors that serve as the surface electrodes 114 of a quantum dot device. The surface electrodes 114 confine charge carriers in the transport layer 106 into a small space or quantum dot QD when a reverse-bias voltage is applied. Quantum confinement of the charge carriers is effected by the negative charge on the surface electrodes 114, which repels the electrons and prevents the horizontal escape of the electrons through the transport layer from a region bounded by a group of the surface electrodes 114. The electrons are thus confined to small regions within the transport layer 106, i.e., the quantum dots QD, where they form artificial atoms that serve as dopants that affect the electrical, thermal, and optical conductivity of the transport layer 106 and the surrounding layers.

The application of an external voltage across the quantum well transport layer 106 will affect the conduction energy of the charge carriers, and thus increase or decrease the number of charge carriers trapped in the transport layer 106 in a controlled manner. The surface electrodes 114 are powered by energy carried in the control path 118. Energy passes into the quantistor 100 through the input path 107, where it is conducted, absorbed, reflected, selectively filtered, or otherwise modified by the artificial dopant atoms in the quantum dots QD within the transport layer 106. Any unblocked energy is then free to exit the switch through the output path 108.

In FIG. 1 the input path 107 and output path 108 are shown as connected to the transport layer 106. However, the quantistor 100 could also function if these paths were attached to the upper barrier layer 104 or lower barrier layer 110 of the quantum well 102, as long as the energy passing between the input path 107 and output path 108 is sufficient to overcome the electrical resistance, thermal insulation, or optical opacity of the barrier layers 104, 110. It is also possible for the input path 107 and output path 108 to be through free space, without a physical conduit, as for example when a photon passes vertically through the various layers of the switch.

For the purposes of this document, the term “switch” refers to a device that may perform functions of both solid-state and mechanical devices for selectively blocking or permitting the flow of energy, including functions of both digital switches (e.g., transistors and relays) and analog switches (e.g., tubes and rheostats). Furthermore, a valve for selectively blocking or regulating the flow of gases or fluids can be considered analogous to a switch, so that in principle the two terms could be used interchangeably. It is also a feature of most switch types, including quantistors, that they can be run in reverse. In other words, while a particular pathway may be identified as the source or input path, and another as the drain or output path, there is not generally any physical or operational barrier to reversing the roles of these two paths, so that energy flows through the device in the opposite direction.

In an exemplary embodiment, the surface electrodes 114, and energy paths 107, 108, and 118 are made of gold. However, the energy paths 107, 108, and 118 may be formed of semiconductor or superconductor materials, optical fiber, or other conduits for carrying energy. The control paths may further be antennas for receiving signals and energy from electromagnetic waves, for example, radio frequency or microwave antennas. Any of the embodiments of control paths or electrodes described herein may be replicated on a molecular scale through the use of specialized molecules such as carbon nanotubes and fullerenes. The quantum dots QD may be other sorts of particles or devices than those discussed herein, so long as they accomplish the quantum confinement necessary for the formation of artificial atoms. In addition, the artificial atoms may be composed of charge carriers other than electrons, for example, protons or “holes.” The number and relative sizes of the quantum dots QD with respect to the quantistor 100 may also be significantly different than is shown in the drawings.

Surface electrodes 114 of appropriate width, thickness, purity, and positional accuracy may be laid down by a number of established methods. These methods include, but are not limited to, for example, lithographic masking procedures such as electron beam lithography and scanning probe anodic oxidation lithography, coupled with etching procedures such as wet chemical etch or dry ion milling, and direct-write procedures such as dip pen nanolithography or nanoimprint lithography. Chemical self-assembly is another optional process which produces an etch mask via the anodic oxidation of aluminum into alumina, or the vitrification of diblock copolymers, or by any other method which spontaneously produces a thin film pierced by a regular array of vertically spaced pores. Less established, but plausible, alternative methods for constructing surface electrodes 114 include assembly by tailored microorganisms or molecular machinery, assembly by atomic pick-and-place, e.g., with a scanning probe microscope, or by atom holography (i.e., exploiting the wavelike properties of atoms at very low temperature). Other viable methods, although not listed here, may also be used, and this listing should not be construed as limiting in scope.

While an exemplary embodiment is depicted and described, it should be understood that the present invention is not limited to this particular configuration. Quantum wells made from other materials and of other designs than described above may be used. Quantum wells designed to trap “holes” or other positive charge carriers are contemplated. Further, heterojunctions or quantum dot particles may be used in place of quantum wells with little change in essential function of the invention. The quantistor 100 may also be protected by an additional insulating layer (not pictured), either continuous or discontinuous, below, above, or surrounding the surface electrodes 114, and/or surrounding the energy paths 107, 108, and 118.

Note that the exact arrangement of the various layers can be slightly different than is depicted in FIG. 1, without altering the essential structure and function of the quantistor. For example, the “sandwich” or composite film may be two-sided, with quantum dot devices on its lower as well as upper surface. In addition, the sandwich may not be flat, but may be folded into a cylinder, sphere, prism, flexible fiber or ribbon, or other shape, including complex forms. For example, the quantistor layers could be applied to the inside surfaces of a porous, three-dimensional material such as a sponge or aerogel. The control paths need not be located at the upper surface of the device, although for some embodiments this may be the most convenient place to locate them. One manner of using the quantistor is to place it as a component within an electronic, optical, optoelectronic, thermoelectric, or mechanical device. Alternately, a plurality of quantistor devices may be stacked together into a three-dimensional structure whose material properties can be affected by external energy sources.

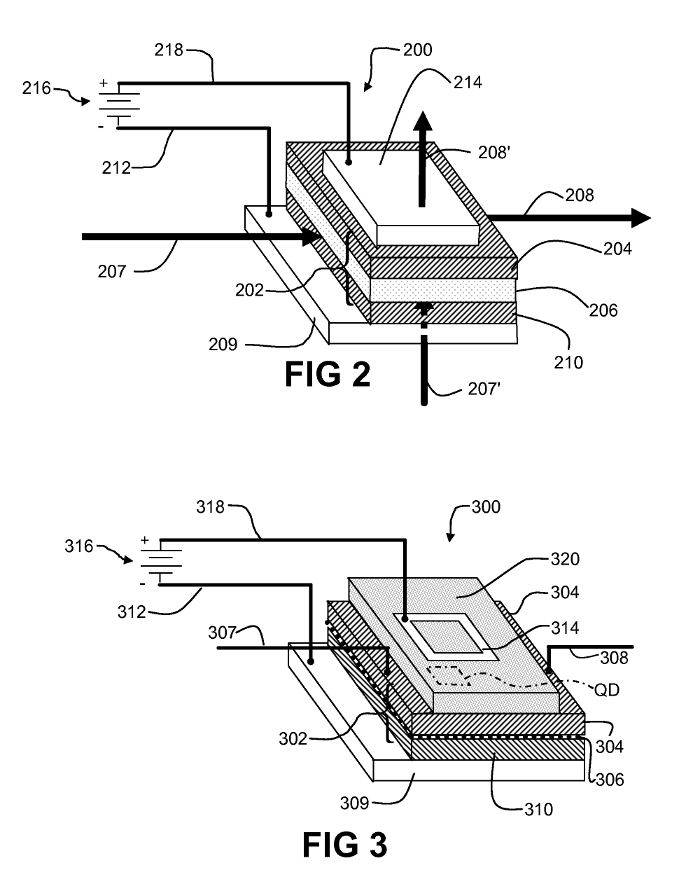

FIG. 2 illustrates a simple form of a quantistor 200 that relies exclusively on the quantum-confined Stark effect. The Stark effect occurs when an electric field is applied perpendicular to a quantum well. The electric field affects the energy level of the carriers confined within the quantum well, which has a slight effect on the absorption spectrum of the quantum well. As in FIG. 1, the quantistor device 200 consists of an upper barrier layer 204, a lower barrier layer 210, a transport layer 206, a surface electrode 214 controlled by a control path 218, and a ground plane 209. In this exemplary form, the device does not produce quantum dots, and therefore does not form three-dimensional artificial atoms. However, electrons or other carriers can still be quantum confined in the vertical dimension within the transports layer 206 by the barrier layers 204 and 210 to form a quantum well 202, producing atom-like carrier behavior in that dimension. When the control path 218 is activated by an external voltage source 216, the ground plane 209 then drains to the return side of the voltage source through the control return path 212. The resulting potential across the quantum well 202 affects the quantum confinement energy of the trapped charge carriers via the quantum Stark effect. This will affect the optical, thermal, and electrical properties of the transport layer 206, particularly in the vertical direction.

In this embodiment, two possible input paths 207, 207′ and output paths 208, 208′ are shown without any conduit. Although input and output conduits could be added to guide the incoming and outgoing energy, the device 200 is also capable of operating as a quantistor without conduits, either in free space or within solid materials or devices, to serve, for example, as a tunable optical filter or tunable thermal insulator. It will be understood by a person skilled in the art that the various methods for adhering and electrically contacting control wires 212, 218 to a conducting or semiconducting surface are well established in the art.

In the configuration of FIG. 2, the maximum static potential across the quantistor device 200 is limited by the bandgap of the semiconductor materials, the breakdown field of the layers 204, 206, 210 of the quantum well 202, and the tunneling current between the surface electrode 214 and the ground plane 209. Above this threshold value, the layered composite film forming the quantistor device 200 will behave as a conductor in the vertical dimension, and the vertical field will be DC rather than static, significantly altering the behavior of the quantisor device 200. However, it is also possible to add an insulating layer (not shown) between the surface electrode 214 and the upper barrier layer 204 of the quantum well 202, or between the lower barrier layer 210 of the quantum well 202 and the ground plane 209. A semiconductor native oxide may be the easiest to introduce, although other materials could also be used without affecting the performance of the device. The addition of this insulator will increase the maximum static potential across the quantistor device 200, allowing for a stronger electric field across the quantum well 202, hence a more pronounced Stark effect.

FIG. 3 illustrates the quantum confinement of charge carriers in three dimensions in a layered composite film forming a quantistor 300. In this embodiment, material layers 304 and 310 form a heterojunction 302. An exemplary composition of the heterojunction 302 is a transport layer 304 of a semiconductor, for example, GaAs, in continuous contact with a barrier or supply layer 310 of a semiconductor with higher conduction energy, for example, AlGaAs. Because of the difference in conduction energies, electrons settle preferentially into the lower energy of the GaAs transport layer 304, leaving holes behind.

However, the electrons are attracted to the holes and tend to remain close to them. Thus, electrons tend to accumulate at the interface between the two layers, forming what is known as a “two dimensional electron gas” 306. This electron accumulation is called a “gas” because the electrons are free to travel horizontally through this interface like the molecules in a gas, but are confined vertically by the material layers 304 and 310 above and below it. In a more general sense, other charge carriers such as holes can be driven into the heterojunction 302, forming the two-dimensional gas 306.

The exact charge density of the gas 306 can be increased or decreased by applying a voltage 316 across the heterojunction 302 using the control path 318 and control return path 312. FIG. 3 also includes an additional insulating layer 320 on top of the heterojunction 302, and one or more surface electrodes 314 on top of the insulating layer 320. A quantum well can be used in place of a heterojunction 302, as shown in FIGS. 1 and 2. If the electrodes 314 are arranged so as to enclose, or nearly enclose, an area above a quantum well or two-dimensionsal electron gas 306 as shown, the electric fields generated by the electrodes 314 can be used to further confine the charge carriers in the gas layer 306. If the charge carriers are confined into a small enough region known as a quantum dot QD, an artificial atom is formed.

In other words, the surface electrodes 314 acquire a net charge. Since like charges repel, a negative charge on the surface electrodes 314 will cause negatively charged charge carriers, e.g., electrons, in the gas layer 308 to be repelled. Similarly, a positive charge on the surface electrodes 314 will repel positive charge carriers. As a result, the uniform “gas” 306 of charge carriers is disrupted, so that charge carriers outside the area enclosed by the electrodes 314 are driven away, while charge carriers inside the enclosed area are driven toward the center. These charge carriers enclosed by the electrodes 314 cannot leave without overcoming the energy barrier of the repulsive force. If the resulting confinement space is smaller than the de Broglie wavelength of the confined charge carriers, then quantum confinement effects will be observed, and the confinement space in the heterojunction 302 is considered a quantum dot QD.

When energy (whether electrical, thermal, optical, or some other form) enters the device through the input path 307, the doping properties of the artificial atoms formed in the quantum dots QD operate on the energy as it passes through the 2D electron gas 302. Such operations include but are not limited to amplification, attenuation, transmission, diversion, rotation, acceleration, shifting, reflection, absorption, delay, echo or repetition, inversion, limiting or clipping, distortion, purification or filtering, regulation, reshaping, reallocation, oscillation, identification or characterization, and storage.

Any remaining unblocked energy is then free to exit the device through the output path 308. In FIG. 3 the input path 307 and output path 308 are shown connected to the transport layer 304. However, the quantistor device 300 could also function if these paths were attached to the barrier or supply layer 310 of the heterojunction 302, as long as the energy passing between the input path 307 and output path 308 is sufficient to overcome the electrical resistance, thermal insulation, or optical opacity of the barrier layer 310. It is also possible for the input path 307 and output path 308 to be through free space, without a physical conduit, as for example when a photon passes vertically through the various layers of the quantistor device 300.

The entire apparatus, including the transport layer 304 and the barrier layer 310 forming the heterojunction 302, the paths 307, 308, 312, 318, the insulating layer 320, and the surface electrodes 314, and the ground plane 309, constitutes the quantistor 300. In an exemplary embodiment, the surface electrodes 314, and energy paths 307, 308, 312, and 318 are made of gold. However, the energy paths 307, 308, 312, and 318 may be formed of semiconductor or superconductor materials, optical fiber, or other conduits for carrying energy. The control paths may further be antennas for receiving signals and energy from electromagnetic waves, for example, radio frequency or microwave antennas. Any of the embodiments of control paths or electrodes described herein may be replicated on a molecular scale through the use of specialized molecules such as carbon nanotubes and fullerenes.

The quantum dots may be other sorts of particles or devices than those discussed herein, so long as they accomplish the quantum confinement necessary for the formation of artificial atoms. In addition, the artificial atoms may be composed of charge carriers other than electrons, for example, protons or “holes.” The number and relative sizes of the quantum dots with respect to the quantistor may also be significantly different than is shown in the drawings. Once the charge carriers are trapped in a quantum dot QD, they form a wave structure known as an artificial atom, which is capable of serving as a dopant for the surrounding material. This principle is exploited to produce the multifunctional, programmable, quantum confinement switch or quantistor. A plurality of quantistor devices could be placed together to create a form of an addressable, doped material whose energy absorbing and transmitting properties can be controlled in real time.

The particular configuration shown in FIG. 3 is not meant to be limiting; quantistor devices may be formed in other shapes. These possibilities include circles, triangles, regular and irregular polygons, open patterns of adjacent lines, and asymmetric shapes in any combination, such as, for example, a circular electrode with a square central opening, a triangular electrode with a circular central opening, or other similar combinations. The three-dimensional analogs of all the aforementioned shapes are also explicitly included as possible embodiments.

Also notable is that the exact arrangement of the various layers of the quantistor may be slightly different than is depicted in FIG. 3 without altering any essential functions. For example, the transport layer 304 does not have to be “on top” of the barrier layer 310 and their positions with respect to each other and the insulating layer 320 and electrode 314 could be reversed, i.e., the electrode 314 and/or the insulating layer 310 could be adjacent the barrier layer 310. Further, a quantum well may be used in place of a heterojunction, a thin metal layer may be sandwiched between semiconducting or insulating layers (as in a thin-film capacitor), or any other method may be used which is capable of confining the charge carrier gas 306 to a thin enough layer that quantum effects will be observed.

The quantistor device 300 will also function without the insulation layer 320, although there may be a substantial leakage current across the transport layer 304 if the voltage on the surface electrodes 314 exceeds the band gap or breakdown voltage of the transport layer 304. If the electrode voltage 316 exceeds the band gap or breakdown voltage of the insulator 320, a current may arc through the insulation layer 320. In either case, for some embodiments of the invention lacking an insulator, the electrode voltage 316 may be selected such that quantum confinement occurs while significant leakage current does not.

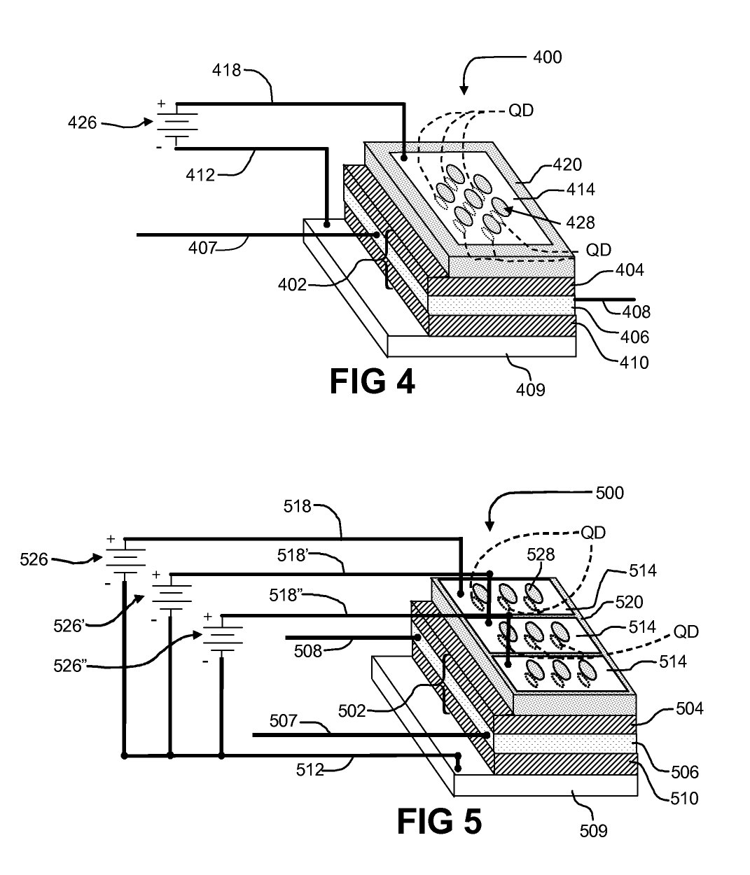

FIG. 4 illustrates the formation of an arbitrary number of quantum dots QD in a quantistor 400. The principle is exactly the same as in FIG. 3, except that the two-dimensional electron gas layer has been replaced with a quantum well transport layer 406, and the surface electrode on top of the insulating layer 420 has been fashioned into a grid electrode 414 with multiple openings 428. These openings 428 may be physical voids in the electrode material 414, e.g., filled with ambient air, vacuum, or liquid, or they may be composed of some other material which is less conductive than the electrode material 414. For example, the electrode grid 414 could be a metal plate interrupted by a regular pattern of milled pits through which electrons cannot easily conduct, or it could be a low-bandgap semiconductor interrupted by a regular pattern of local oxidation, where the oxide has a higher bandgap than the semiconductor and thus impedes the entry or passage of electrons.

If the grid openings 428 are smaller than or comparable to the de Broglie wavelength of the confined carriers, then quantum confinement effects will be observed when the quantum well 402 and surface electrode 414 are charged as described above. Specifically, one quantum dot QD is formed in the transport layer 406 of the quantum well 402 between the barrier layers 404 and 410 beneath each opening 428 in the grid electrode 414, by the same principles discussed above. Thus, a plurality of artificial atoms is created in the quantistor 400 corresponding to each opening 428 in the grid electrode 414.

The operation of the embodiment of FIG. 4 is very similar to embodiment of FIG. 3, except that alteration of the voltage 426 across the device 400 will produce parallel changes in all of the artificial atoms at once. In the specific case where the grid openings 428 are of precisely equal size and spacing, and the distribution of charge carriers in the transport layer 406 of the quantum well 402 is uniform, the artificial atoms formed in the quantum dots QD will be identical. Changes in atomic number of the artificial atoms will be uniform across the quantum dots QD and thus doping properties will occur in the same ways and at the same time when the control voltage 426 across the quantistor device 400 is altered. Thus, the complete quantistor 400 will include a grid of identical, programmable, artificial atoms.

When electrical, thermal, optical, or other energy is passed into the device through the input path 407, it is selectively blocked, filtered, or modified by the doping effects of these artificial atoms. Any unblocked energy is then free to leave the device through the output path 408.

In an alternate embodiment, wherein the grid openings 428 are of nonuniform size, shape, or spacing and/or the charge carriers in the transport layer 406 are of nonuniform initial distribution, the artificial atoms may or may not be identical, and may or may not respond in identical ways to the influence of the control voltage 426. However, in this case each individual artificial atom will still respond consistently to any particular voltage setting, and the net behavior of the system will be fully repeatable. As a result, in either case the quantistor 400 depicted in FIG. 4 is capable of serving as a multifunctional, programmable, quantum confinement switch.

A person of ordinary skill in the art will understand that the methods for forming a grid-shaped electrode are similar to those for forming an electrode of any other shape, and need not be described here. However, a partial list would include techniques such as electron beam lithography and anodic oxidation lithography using the probe tip of a scanning probe microscope. It should also be noted that certain lithographic processes are particularly well suited for the nanopatterning of macroscopic areas. These include photolithography (particularly extreme ultraviolet or EUV photolithography), atom holography, and nanoimprint lithography, whether directly depositional or relying on the contamination and later developing and stripping of a “resist” layer, lend themselves to the rapid production of large and relatively uniform grids. Other methods, for example, X-ray crystallography, are capable of producing extremely fine interference patterns that may be used to expose a resist and produce grid-like patterns in a metal layer, which can be used to divide a quantum well or heterojunction into quantum dot regions.

In addition there are molecular self-assembly processes such as the anodization of aluminum into alumina, or the glassification of carefully designed diblock copolymers, which create a thin membrane or “mask” of material pierced by a regularly spaced array of vertical pores, typically arranged in a hexagonal symmetry. A milling process such as reactive ion etching (RIE) can then be used to remove the metal directly beneath a pore, while leaving the metal beneath the solid mask intact. These methods for producing the grid electrode 428 or other electrodes of a quantistor are also embodiments of the present invention, although this should not be construed as limiting the scope of the invention. A quantistor 400 of the type shown in FIG. 4 can be produced by other methods not described here, with no change in its essential function. It should also be understood that the quantistor device 400 as depicted in FIG. 4 can be scaled upward in two dimensions, increasing the number of quantum dots QD almost without limit.

Notably, placing the quantum dots close together produces constructive interference between the electric fields which produce them, making the fields stronger. This has the effect of decreasing the effective size of the quantum dots, and therefore increasing their quantum confinement energy. In many cases this constructive interference is necessary to produce a device that can operate at or above room temperature. Without constructive interference, the quantum dots would be larger, and their energies lower, so that the quantum confinement energy of the trapped carriers would be less than the thermal energy of a room-temperature electron, making quantum confinement impossible.

Whether constructive interference is required or merely incidental, the close packing of quantum dots increases the density of artificial dopants in a transport layer or heterojunction, and therefore increases their doping effects. However, if the dots are packed too closely, the surface electrode will be easily disrupted by small cracks, impurities, or other flaws in its conductive material, and the device will not function. It should also be noted that there is a maximum and minimum value for the size of the electrode grid openings, as well as their spacing, in order for the electric fields to assume the desired shape for quantum confinement. Thus, the exact behavior of the device under specific environmental conditions is a function of these various dimensions.

In one exemplary implementation according to the embodiment of FIG. 4, the surface electrode 414 may consist of a 10 nanometer thick layer of gold with a 3 nanometer adhesion layer of titanium beneath it. The barrier layer 404 may be composed of aluminum gallium arsenide approximately 5 nm thick, with the insulator 420 being the native oxide of that material, which is normally approximately 2 nm thick. The quantum well transport layer 402 may be composed of gallium arsenide and is approximately 6-12 nm thick, and the ground plane 409 may be composed of n-doped gallium arsenide with very low resistivity.

The surface electrode 414 may be patterned by first spin-coating it with a surface treatment consisting of a random copolymer of styrene (S), 4-vinyl benzocyclobutene (BCB), and methyl methacrylate (MMA) with proportions S/BCB/MMA equal to 56/2/42, with an average molecular weight of approximately 35,000, dissolved in the solvent toluene. The device is then heated in a nitrogen atmosphere, and then a diblock copolymer consisting of 70% styrene and 30% MMA, with a molecular weight of approximately 122,000 is applied by the same spin coating method. The device is then heated in vacuum beyond the glass transition temperature of the polymers, cooled to room temperature, exposed to ultraviolet light and then rinsed in acetic acid.

The resulting polymer membrane has a hexagonal array of pores whose size and spacing is proportional to the molecular weight of the diblock copolymer—in this case approximately 30 nm diameter and 52.5 nm center-to-center spacing. The device is placed in a reactive ion etcher to remove the metal beneath the pores, and then the polymer is stripped off. A mask is then applied so that the metal surface electrode 414, and possibly the insulator 420 and upper barrier layer 404 can be etched away in selected regions with the reactive ion etcher. The input path 407 and output path 408, and bias voltage control paths 412, 418, are next attached to the transport layer 406, upper barrier 404, or insulator 420, leaving a finished device 400. This method can be used to pattern wafer surfaces from 0.5 cm to 20 cm in diameter with approximately equal difficulty, and can also be used to pattern larger or smaller areas. This example is included for illustrative purposes only and should in no way be construed as limiting in scope.

In another exemplary implementation, the composition and arrangement of the metal surface electrode and semiconductor layers is the same, but the surface of the device is spin-coated with the lithographic resist polymethyl methacrylate (PMMA), and then patterned with an array of holes via anodic oxidation lithography using the probe tip of a scanning probe microscope. The tip is held a few nanometers from the surface, and then biased so that an electron beam passes between the tip and the surface, exposing the PMMA resist. The device is then rinsed with a developer solution that removes the exposed PMMA, leaving behind a polymer mask with hole size and spacing depending on the bias voltage and programmed motion of the probe tip. The device is then etched and cleaned and the control paths attached as in the previous example. A hole diameter of approximately 70 nm, with center-to-center spacing of approximately 74 nm, has been found to work well. An electron microscope can be used in place of a scanning probe microscope for the lithography step, although the “proximity effect” makes it more difficult to place features close together. This description is included for explanatory purposes only and should in no way be construed as limiting in scope.

FIG. 5 illustrates another embodiment, wherein the quantistor device 500 includes a plurality of electrodes 514 and control paths 518, 518′, 518″. A quantum well 502 is again formed by the interface between an upper barrier layer 504, a transport layer 506, and a lower barrier layer 510. Discretre voltages 526, 526′, 526″ are applied between the control paths 518, 518′, 518″ and the control return path 512. The operation of this quantistor device 500 is very similar to that described for FIG. 4, except that each electrode 514 is connected to a separate control path 518, 518′, 518″ and is controlled by a separate external voltage source 526, 526′, 526″, although they all share a common ground plane 509. As in FIG. 4, quantum dots QD are formed in the transport layer 506 beneath the area of the insulating layer 520 bounded by the surface electrodes 514 when the surface electrodes 514 are charged. Collectively, these components constitute the quantistor 500.

As depicted, in the embodiment of FIG. 5, each of the surface electrodes 514 has a separate control path 518, 518′, 518″ contacted with it, and is controlled by a separate external voltage source 526, 526′, 526″. It should also be understood that while only three surface electrodes 514 are depicted in the quantistor 500 of FIG. 5, the quantistor devices 500 may incorporate an arbitrarily large number of electrodes. However, it is possible and often desirable for multiple of the surface electrodes 514 to be connected to a common external voltage source, so that the surface electrodes 514 are controlled in groups by a relatively small number of independent voltages. It should also be understood that the exact shape and position of the surface electrodes 514 could be quite different than what is pictured, so long as the resulting structure is capable of achieving quantum confinement as defined above.

The advantage of the design of the quantistor 500 of FIG. 5 incorporating multiple electrodes 514 is that by selecting different voltages on these electrodes 514 it is possible to alter the repulsive electric field, thus affecting size and shape of the confinement regions of the quantum dots QD. This necessarily alters the size and shape of the artificial atom trapped inside the quantum dots QD, either in conjunction with changes to the artificial atom's atomic number or while holding the atomic number constant. Thus, the doping properties of the artificial atoms may be adjusted in real time through variations in the charge of the electrodes 514. Since each electrode 514 can create different doping properties than the electrodes 514 that are adjacent to it, it then becomes possible to create junctions of different material types within the transport layer 506 of the quantum well 502. This creates the opportunity for more complex types of switching or filtering within the quantistor 500, much as a FPGA allows the creation, whether temporary or permanent, of electronic circuits within it.

As a side effect of this design, it is also possible for the quantistor 500 to generate electricity in certain of its “on” or “closed” states. When the quantum dots QD under one electrode 514 are adjusted to perform as “p” type dopants, while the quantum dots QD under an adjacent electrode 514 are adjusted to perform as “n” type dopants, a p-n junction or diode may be formed within the transport layer 506. This structure can generate electricity from light passing through it, by means of the photoelectric and photovoltaic effects used in solar cells and photodiode sensors. The quantistor 500 can also generate thermoelectricity from a thermal gradient using the Peltier-Seebeck effect, the Thompson effect, or by acting as a semiconductor thermocouple. In this case, the generated electricity would create a potential or voltage between the input path 507 and output path 508. The photoelectric and thermoelectric processes can also be run in reverse, using an electrical potential between the input path 507 and output path 508 to generate photons or a temperature gradient. With four or more control paths and surface electrodes, the transport layer 506 can be used to create even more complex material interfaces including superlattices, as well as 2-dimensional structures such as circuit traces. These structures and their uses are well understood in the art and need not be further elaborated here.

The artificial atoms in the quantum dots QD, like natural atoms, can also have a net spin imbalance among their electrons. In this case they will generate a magnetic field that can be used to affect charge carriers moving through the transport layer 506, and the neighboring barrier layers 504 and 510. The magnetic field can also be used to generate electricity (i.e., a voltage between the input path 507 and output path 508) or photons, since the acceleration of a charged particle through a magnetic field creates an electric field or potential gradient, and the deceleration of a charged particle causes kinetic energy to be converted into photon energy, for example, as radio waves. These electromotive effects are well understood in the art and need not be further elaborated here.

As a consequence of its design, the quantistor 500 depicted in FIG. 5 will generally exhibit some level of electro-optical, thermoelectric, and electromotive behavior in any “on” or “closed” state. Thus, the quantistor 500 can be used as either a power source or as a sensor or emitter when configured in a state where these effects generate significant voltages. In other possible states where these effects do not significantly alter the functioning of the device, and thus are not directly measurable, the quantistor device 500 does not act as an emitter, power source or sensor.

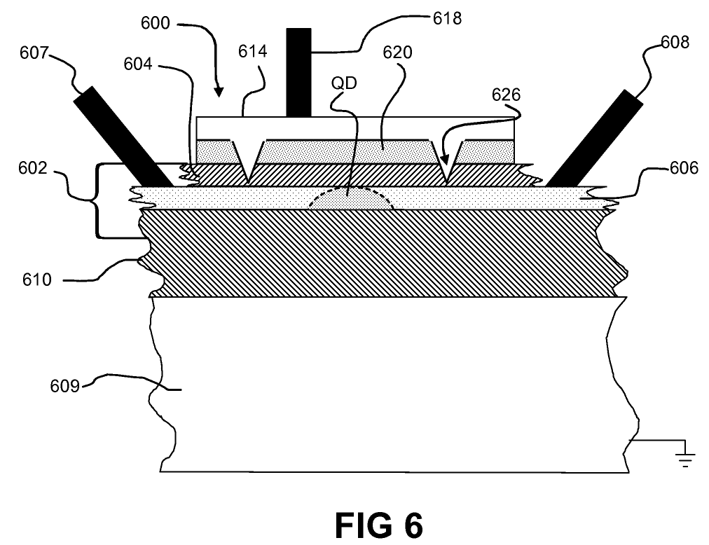

FIG. 6 discloses an additional embodiment of a quantistor 600 in which openings in the surface electrodes 614 are not mandatory. Instead, there are conductive cleats 626 which are electrically contacted to the surface electrode 614, and which project down through one or more of the semiconductor layers underneath. In the embodiment shown in FIG. 6, the cleats 626 penetrate through the insulator 620 and into the upper barrier layer 604. However, in some embodiments, it my be desirable to have the cleats 626 penetrate deeper, so that the cleats 626 passes through the transport layer 606, the lower barrier layer 610, or possibly even directly into the ground plane 609. Similarly, the embodiment in this figure shows the cleats 626 as conical in shape. However, in other embodiments the cleats 626 could be cylinders, hemispheres, rectangular prisms, or any other shape that connects the charged conductor of the surface electrode 614 to deeper layers in the wafer. In one embodiment, the cleats 626 are made of the same material as, and are continuous with, the surface electrodes 614.

The manufacture of the quantistor device 600 of FIG. 6 is similar to those already discussed, except that before metallization, the quantum well wafer (consisting of the ground plane 609, the lower barrier layer 610, the transport layer 606, the upper barrier layer 604, and insulator 620) is milled with a pattern of holes using any of the methods already described, or by some other method. A conducting material is then laid down in such a way as to fill the holes and coat the surface of the wafer, forming both the cleats 626 and the surface electrode 614. In an exemplary form, this conductive material is an alloy of 60% gold and 40% palladium, which is mechanically strong, resistant to oxidation and other corrosion, adheres well to semiconductor surfaces, and can be laid down with an inexpensive sputter coater of the sort often employed in electron microscopy. However, this example is included for descriptive purposes only, and should not be construed as limiting in scope. Almost any conductive material, including metals, polymers, electrolytic gels or liquids, and molecular monolayers could serve an equivalent function.

The cleats 626 alter the electric field created by the surface electrode 614, creating quantum dots QD in the transport layer 606 of the quantum well 602, in the regions between the cleats 626 as shown in FIG. 6. The operation and functioning of the quantistor device 600 are otherwise similar to the embodiments already described. Note that while FIG. 6 shows the surface electrode 614 as having no openings, it is advantageous under some circumstances to include an opening in the electrode 614 above the quantum dot QD, as this has a significant effect on the shape of the electric field produced by the surface electrode 614 and cleats 626.

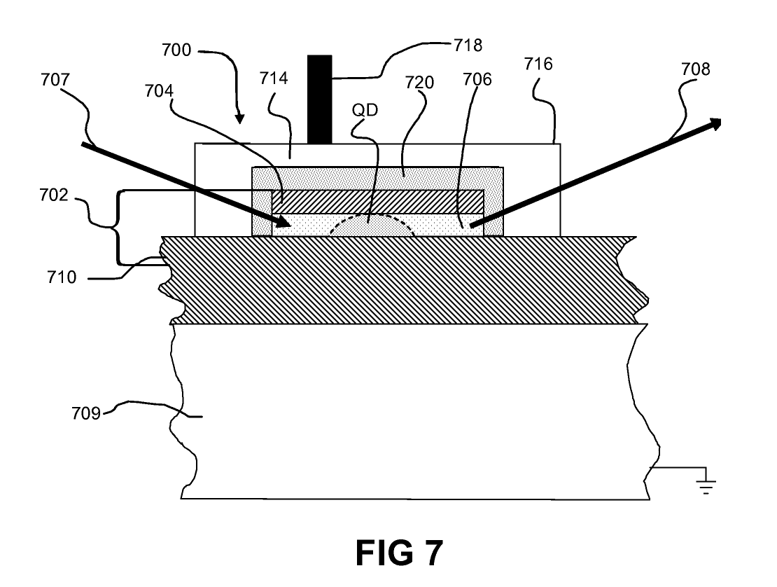

FIG. 7 discloses another implementation in which the upper layers of the quantum well 702, including the insulator 720, the upper barrier layer 704, and the transport layer 706 have been etched into an “island” shape 716. This can be accomplished using a variety of lithographic techniques which are well known in the art. In an exemplary case, this etching may be accomplished with electron-beam lithography and reactive ion etching. In addition, it is possible to grow the quantum dots QD using strain-based growth techniques such as the deposition of indium-gallium-arsenide on a gallium-arsenide surface using molecular beam epitaxy, which produces 3D structures on the surface (e.g., pyramids) with no need for etching. Many of these techniques, involving the addition or removal of material, or both, have already been discussed herein, but other techniques could be used, including techniques now known or hereinafter devised, without altering the essential function of the device. The examples given should not be construed as limiting the scope of the invention. In this embodiment the island 716 is shown in FIG. 7 as a cylindrical or rectangular shape, although other shapes could be used. In particular many growth techniques produce quantum dots of pyramidal or hemispherical shape, a property which is well known in the art and need not be further elaborated.

If the horizontal diameter of the island 716 is less than the de Broglie wavelength of a confined carrier, then the entire transport layer 706 within the island 716 will function as a quantum dot QD. If the diameter is greater than the de Broglie wavelength, the transport layer 706 will function as a quantum well 702. However, in either case the insulator layer 720 is grown so that it covers the sides of the island 716. The easiest way to accomplish this is to allow the surface to oxidize, although other methods could be used. The surface electrode 714 can be deposited in such a way that it also covers the sides of the island 716, so that its electric field can be used to repel electrons or other carriers when activated by the control path 718, forcing the carriers toward the center of the island and producing a quantum dot QD.

Note that for this effect to occur it is not necessary for the surface electrode 714 to cover the top surface of the island 716, although this arrangement seems convenient. In this embodiment it is also not necessary for the island 716 to contain a top barrier layer 704, although one is shown here for clarity. The device is also capable of functioning without the insulator 720, although this means that a Shottkey diode (i.e., a metal-semiconductor junction) forms the only potential barrier between the surface electrode 714 and the transport layer 706, limiting the amount of voltage that can be applied without creating a DC current through the quantistor device 700 and altering its function as a multifunctional, programmable, quantum confinement switch. Alternatively, the island 716 can be narrow enough that it serves as a quantum dot QD without any electric field encroaching on it from the sides. In this case, the surface electrode 714 does not need to cover the sides of the island 716, although it does need proximity to some portion of the island 716 in order to affect its doping properties.

Once the quantum dot QD has been activated by the surface electrode 718, the energy entering the device through the input path 707 is then blocked, filtered, or otherwise modified by the artificial atom inside the quantum dot QD, and the remaining unblocked energy is free to leave the device through the output path 708. The exact behavior of the quantistor 700 is a function of the thickness of the various layers, the size of the island 716, and the voltage between the control path 718 and the ground plane 709.

Although the device is depicted in FIG. 7 as including only one island 716 and producing only one quantum dot QD, the invention includes embodiments where a plurality of these structures exist, either controlled by one continuous surface electrode 714 or else controlled in banks by multiple surface electrodes, as in FIG. 5.

From the description above, the quantistor can be seen to provide a number of capabilities. First, the quantistor provides a multifunctional switch with the ability to switch or regulate the flow of electricity, light, heat, and other energy in a single device, simply by varying the voltage between the control path and the ground plane. Alternatively, this voltage could be held constant while other parameters, such as temperature gradients, ambient radiation, or electric fields from external devices, are varied. Second, the quantistor provides a solid-state means for switching or regulating the flow of heat. Third, the quantistor provides a switch whose properties can be reprogrammed dynamically via external signals. Fourth, the quantistor provides a switch that is capable, as a side effect of its design, of using the energy that passes through it to generate electricity. Fifth, the quantistor provides a switch that is also capable of serving as a multifunctional sensor. Sixth, it is possible to place a multiplicity of quantistor devices in close proximity, forming a “smart material” whose bulk properties can be adjusted dynamically.

Several advantages of the quantistor also become evident. The quantistor makes it possible to control the flow of heat inside a solid-state device (e.g., a computer chip), without the addition of any moving parts, and also makes it possible to generate electricity in the process. In addition, the quantistor provides a multifunctional, programmable device whose essential nature and function can be redesigned to suit the needs of the moment, without any a priori knowledge of the frequency, intensity, or form of the energy being switched, regulated, filtered, or measured, and without any prior assumption about the nature of the desired output. (In this sense the quantistor is more analogous to an FPGA than to a single switch such as a transistor). The quantistor can generate electricity simultaneously using three different principles—thermoelectric, photovoltaic, and electromotive—all at the same time. Also, the quantistor can be used to generate light, radio waves, or temperature gradients, all in a single device, so that it can substitute for a crystal oscillator, light emitting diode, thermoelectric pump, or generator. Finally, the horizontal dimensions of the quantistor can be made arbitrarily large, or can be made approximately as small as the de Broglie wavelength of an electron at room temperature. Thus, the quantistor can fill a variety of uses from window glass to nanoelectronics, including (for example) serving as an individual pixel in a display screen.

The quantistor can be used as a solid-state electrical switch, akin to a transistor, but with a huge variety of other uses as well. Exemplary uses may include as a programmable optical shutter or filter; as a solid-state substitute for thermal relays with bulky moving parts; as a thermoelectric, optoelectronic, photovoltaic, or electromotive device (e.g., a multifunctional sensor); and as a means of generating electricity from a variety of different energy types. Although the input and output pathways may be physical conduits of some type (e.g., electrical wires), it is also possible for the input and output signals to pass through free space (e.g., as light rays) without altering the essential functioning of the device.

A multiplicity of quantistors can be connected in a wide variety of ways to produce new devices. Quantistors can serve as a new type of memory or logic gate, including “thermal bits” which use heat rather than charge or magnetism to carry and store information. Thus, quantistors could be used to produce a “thermal computer,” whether analog or digital. This might have application in, for example, the control of high-temperature components within an engine. For devices that require particular operating conditions, these conditions can also be generated within the quantistor, or by neighboring quantistors. For example, thermoelectric effects can be used to cool a particular region so that a low-temperature device (e.g., a long-wavelength infrared sensor) can operate there.

Although the description above contains many specificities, these should not be construed as limiting the scope of the invention but rather construed as merely providing illustrations of certain exemplary embodiments of this invention. There are various possibilities for making the quantistor of different materials, and in different configurations. It may also be desirable, for example, to employ electrically conductive molecular wires, such as carbon nanotubes, as the control wires and surface electrodes. It should also be noted that while the GaAs family of materials is used in exemplary form within this document in the creation of quantum dots and quantistors, a huge variety of different materials could be used instead, including insulators, semiconductors, conductors, or superconductors. There are particular advantages to using higher-bandgap materials, as they not only allow for energetically “deeper” quantum wells, but in many cases also allow the quantum well, including the ground plane or other substrate, to be transparent to visible light. Such embodiments are explicitly included as part of the present invention.

Numerous other variations exist which do not affect the core principles of the invention's operation. For example, the charge carriers could be confined using magnetic fields instead of or in addition to electric fields. For example, laser light (which consists of both magnetic and electric fields) could be used as a confinement mechanism. Also, the quantistor need not be flat or two-dimensional, but could be folded into, wrapped around, or otherwise formed into other shapes. Such shapes include, but are not limited to, cylinders, spheres, cones, prisms, and polyhedrons, both regular and irregular, asymmetric forms, and other two- and three-dimensional structures. The device could also be employed in flexible forms such as sheets, fibers, and ribbons, with quantum dot devices on one or both surfaces. It is also conceivable to grow the quantistor on the inside surface of a complex, porous, or “spongy” material/structure such as an aerogel. The quantistor could employ a single quantum dot instead of a plurality, and could include multiple input pathways (to serve as, for example, a mixer or signal combiner) or multiple output pathways (to serve as, for example, a signal splitter or diverter), or both. In the extreme case of a quantistor with multiple inputs, multiple outputs, and multiple control paths, the device could arguably be considered a field programmable quantistor array (FPQA) rather than a single quantistor, but the distinction is moot, since both devices fit the description given in this specification.

When formed into bulk materials, multiple layers of quantistor devices with programmable dopants could be stacked into three-dimensional structures and formed into “smart materials.” However, numerous other methods could be used to pack and control the highest possible density of quantum dots. For example, the films could be rolled into a fiber shape and woven or braided. Equally, they could be folded into cubes or other shapes and stacked together three-dimensionally. Other favorable packing configurations are possible as well, many of which will serve to further increase the constructive interference between neighboring quantum dots.

Although various embodiments of this invention have been described above with a certain degree of particularity, or with reference to one or more individual embodiments, those skilled in the art could make numerous alterations to the disclosed embodiments without departing from the spirit or scope of this invention. It is intended that all matter contained in the above description and shown in the accompanying drawings shall be interpreted as illustrative only of particular embodiments and not limiting. All directional references e.g., proximal, distal, upper, lower, upward, downward, left, right, lateral, front, back, top, bottom, above, below, vertical, horizontal, clockwise, and counterclockwise are only used for identification purposes to aid the reader's understanding of the present invention, and do not create limitations, particularly as to the position, orientation, or use of the invention. Connection references, e.g., attached, coupled, connected, and joined are to be construed broadly and may include intermediate members between a collection of elements and relative movement between elements unless otherwise indicated. As such, connection references do not necessarily imply that two elements are directly connected and in fixed relation to each other. Changes in detail or structure may be made without departing from the basic elements of the invention as defined in the following claims.

What is claimed is:

1. A multifunctional quantum switching device comprising
a material fashioned into a thin, flexible film;
a quantum dot physically connected with the material;
a control path physically connected with the material and operatively coupled with the quantum dot, wherein the control path is adapted to carry energy from a controllable energy source to the quantum dot;
an input path operatively coupled with the quantum dot and adapted to input energy to the quantum dot;
an output path operatively coupled with the quantum dot and adapted to output energy from the quantum dot; and
a plurality of charge carriers capable of being confined within the quantum dot to form a an artificial atom; wherein
the energy is adapted to cause an electric potential across the quantum dot to thereby confine a respective subset of the plurality of charge carriers in a controlled configuration within the quantum dot to form a respective the artificial atom;
the energy determines the size, shape, atomic number, and/or energy level of the artificial atom; and
the artificial atom alters the electrical, optical, thermal, and/or magnetic properties of the quantum switching device such that a quantity and type of energy received via the input path is modified before exiting through the output path.

2. The quantum switching device of claim 1, wherein
the quantum dot comprises a plurality of quantum dots;
the control path comprises a plurality of control paths each connected to a respective one of the plurality of quantum dots;
the input path comprises a plurality of input paths each connected to a respective one of the plurality of quantum dots; and
the output path comprises a plurality of output paths each connected to a respective one of the plurality of quantum dots; and wherein
the energy source is differentiable between each of the plurality of control paths and the subset of the plurality of charge carriers is differentiable between each respective quantum dot.

3. The device of claim 2, wherein each of the plurality of control paths is coupled with a respective group of the plurality of quantum dots.

4. The quantum switching device of claim 1, wherein
the quantum dot is a quantum dot device further comprising
a transport layer; and
a barrier layer; wherein
the transport layer and the barrier layer together form a heterojunction; and
the quantum switching device further comprises an electrode supported on the film and operatively coupled with the control path; wherein
the charge carriers are confined by an electric field generated by the electrode within a gas layer of the heterojunction to form the artificial atom.

5. The quantum switching device of claim 1, wherein
the quantum dot is a quantum dot device further comprising
a first barrier layer;
a second barrier layer; and
a transport layer located between the first barrier layer and the second barrier layer; and
the quantum switching device further comprises an electrode supported on the film and operatively coupled with the control path; wherein
the charge carriers are confined by an electric field generated by the electrode within the transport layer to form the artificial atom.

6. The quantum switching device of claim 4 further comprising an insulating medium that insulates the electrode from the quantum dot device.

7. The quantum switching device of claim 5 further comprising an insulating medium that insulates the electrode from the quantum dot device.

8. The quantum switching device of claim 1, wherein the control path comprises an electrode grid.

9. The quantum switching device of claim 1, wherein the control path comprises an array of electrodes electrically insulated from each other on the material.

10. The quantum switching device of claim 1, wherein the control path comprises an electrode having cleats that extend within the quantum dot.

11. The quantum switching device of claim 1, wherein the quantum switching device operates as at least one of the following: a solid state electrical device, an optical shutter, an optical filter, a thermovoltaic generator, a photovoltaic generator, an electromotive generator, a thermal memory, a thermal logic gate, a thermal switch, and a thermal regulator.

12. A device for producing quantum effects, comprising
a thin, flexible film further comprising;
a transport layer; and
a barrier layer; wherein
the transport layer and the barrier layer together form a heterojunction;
at least one electrode supported on the film;
at least one control path operatively coupled with the at least one electrode, wherein the at least one control path is adapted to carry energy from a controllable energy source to the at least one electrode;
at least one input path operatively coupled with the transport layer and adapted to input energy to the transport layer;
at least one output path operatively coupled with the transport layer and adapted to output energy from the transport layer; and
a plurality of charge carriers capable of being confined within the transport layer of the heterojunction to form at least one artificial atom; wherein
when energized, the at least one electrode produces an electric field that interacts with the heterojunction causing the formation of one or more potential barriers, which create at least one quantum dot;
at least one subset of the charge carriers is confined in the at least one quantum dot in the gas layer of the heterojunction in a controlled configuration to form the at least one artificial atom;
the energy determines the size, shape, atomic number, and/or energy level of the at least one artificial atom; and
the at least one artificial atom alters the electrical, optical, thermal, and/or magnetic properties of the quantum switching device such that a quantity and type of energy received via the at least one input path is modified before exiting through the at least one output path.

13. The quantum switching device of claim 12, wherein
the at least one electrode comprises a plurality of electrodes, which are electrically insulated from each other on the film;
the at least one control path comprises a plurality of control paths; and
a subset of the plurality of control paths is electrically coupled with a respective subset of the plurality of electrodes.

14. The quantum switching device of claim 12, wherein the at least one electrode comprises a grid.

15. The quantum switching device of claim 12 further comprising an insulating medium that insulates the at least one electrode from the transport layer, the barrier layer, or both.

16. The quantum switching device of claim 12, wherein the electrode further comprises at least one cleat that extends within the transport layer, the barrier layer, or both.

17. The quantum switching device of claim 12, wherein the quantum switching device operates as at least one of the following: a solid state electrical device, an optical shutter, an optical filter, a thermovoltaic generator, a photovoltaic generator, an electromotive generator, a thermal memory, a thermal logic gate, a thermal switch, and a thermal regulator.

18. A device for producing quantum effects, comprising
a thin, flexible film further comprising
a first barrier layer;
a second barrier layer; and
a transport layer located between the first barrier layer and the second barrier layer;
at least one electrode supported on the film;
at least one control path operatively coupled with the at least one electrode, wherein the at least one control path is adapted to carry energy from a controllable energy source to the at least one electrode;
at least one input path operatively coupled with the transport layer and adapted to input energy to the transport layer;
at least one output path operatively coupled with the transport layer and adapted to output energy from the transport layer; and
a plurality of charge carriers capable of being confined within one or more specific areas of the transport layer to form a at least one artificial atom; wherein
when energized, the at least one electrode produces an electric field that interacts with the first barrier layer, the second barrier layer, and the transport layer causing the formation of one or more potential barriers, which create at least one quantum dot;
at least one subset of the charge carriers is confined in the at least one quantum dot in a controlled configuration to form the at least one artificial atom;
the energy determines the size, shape, atomic number, and/or energy level of the at least one artificial atom; and
the at least one artificial atom alters the electrical, optical, thermal, and/or magnetic properties of the quantum switching device such that a quantity and type of energy received via the at least one input path is modified before exiting through the at least one output path.

19. The quantum switching device of claim 18, wherein
the at least one electrode comprises a plurality of electrodes, which are electrically insulated from each other on the film;
the at least one control path comprises a plurality of control paths; and
a subset of the plurality of control paths is electrically coupled with a respective subset of the plurality of electrodes.

20. The quantum switching device of claim 18, wherein the at least one electrode comprises a grid.

21. The quantum switching device of claim 18 further comprising an insulating medium that insulates the at least one electrode from one, more, or all of the first barrier layer, the second barrier layer, or the transport layer.

22. The quantum switching device of claim 21, wherein the insulating layer encapsulates surfaces of the first barrier layer and the transport layer exposed above the second barrier layer.

23. The quantum switching device of claim 22, wherein the electrode encapsulates exposed surfaces of the insulating layer.

24. The quantum switching device of claim 18, wherein the electrode further comprises at least one cleat that extends within one, more, or all of the first barrier layer, the second barrier layer, or the transport layer.

25. The quantum switching device of claim 18, wherein the quantum switching device operates as at least one of the following: a solid state electrical device, an optical shutter, an optical filter, a thermovoltaic generator, a photovoltaic generator, an electromotive generator, a thermal memory, a thermal logic gate, a thermal switch, and a thermal regulator.

26. A quantistor comprising
a quantum dot;
a control path operatively coupled with the quantum dot, wherein the control path is adapted to carry energy from a controllable energy source to the quantum dot;
an input path operatively coupled with the quantum dot and adapted to input energy to the quantum dot;
an output path operatively coupled with the quantum dot and adapted to output energy from the quantum dot; and
a plurality of charge carriers capable of being confined within the quantum dot to form a an artificial atom; wherein
the energy is adapted to cause an electric potential across the quantum dot to thereby confine a respective subset of the plurality of charge carriers in a controlled configuration within the quantum dot to form a respective the artificial atom;
the energy determines the size, shape, atomic number, and/or energy level of the artificial atom; and
the artificial atom alters the electrical, optical, thermal, and/or magnetic properties of the quantistor such that a quantity and type of energy received via the input path is modified before exiting through the output path.
